(19) United States
(12) Patent Application Publication
(10) Pub. No.: US 2014/0095962 A1
(43) Pub. Date: Apr. 3, 2014

(54) SEMICONDUCTOR DEVICE AND OPERATING METHOD THEREOF

(71) Applicant: SK hynix Inc., Icheon-si Gyeonggi-do (KR)

(72) Inventors: Young-Suk MOON, Icheon-si Gyeonggi-Do (KR); Yong-Kee KWON, Seoul (KR); Hong-Sik KIM, Seongnam-si Gyeonggi-do (KR)

(73) Assignee: SK hynix Inc., Icheon-si Gyeonggi-do (KR)

(21) Appl. No.: 13/963,692

(22) Filed: Aug. 9, 2013

(30) Foreign Application Priority Data
Sep. 28, 2012 (KR) 10-2012-0109057

(51) Int. Cl. G11C 29/00

(52) U.S. Cl. CPC G11C 29/783
USPC 714/773

(57) ABSTRACT

An operating method of a semiconductor device may comprise monitoring error handling information for a data read from a semiconductor memory device; and generating a refresh request for one or more memory cells of the semiconductor memory device according to the error handling information.

### CROSS-REFERENCE TO RELATED APPLICATIONS

The present application claims priority of Korean Patent Application No. 10-2012-0109057, filed on Sep. 28, 2012, which is incorporated herein by reference in its entirety.

### BACKGROUND

1. Technical Field

Embodiments of the present invention generally relate to a semiconductor device and an operating method thereof, and more particularly, to a semiconductor device capable of refreshing one or more memory cells considering error handling information on a data read from a semiconductor memory device, and an operating method thereof.

2. Related Art

With the increase in the integration degree of a semiconductor memory device, a variable retention time (VRT) effect which makes charge retention characteristics of a memory cell change while the semiconductor memory device in use has occurred.

If charge retention time becomes shorter than a refresh period, there occur errors. Though these errors can be categorized as a soft error which is different from a hard error occurring at a fixed position continuously, they may become degenerate into uncorrectable errors if they occur with another soft error or another hard error.

Generally, a semiconductor memory device like DRAM (Dynamic Random Access Memory) is controlled by a memory controller. The memory controller usually comprises a refresh controller which controls refresh operations of the semiconductor memory device. When the refresh controller send refresh request to an arbitration block in the memory controller, the arbitration block pauses to process read and write requests from a host and begins to process the refresh request.

Since the memory controller according to a prior art controls refresh operations with the same refresh period throughout the entire region of the semiconductor memory device, it cannot deal with errors caused by VRT effect occurring at randomly located cells of the semiconductor memory device.

### SUMMARY

Various embodiments are directed to a semiconductor device capable of refreshing one or more memory cells considering error handling information on a data read from a semiconductor memory device and an operating method thereof.

In an embodiment, an operating method of a semiconductor device may include: monitoring error handling information for a data read from a semiconductor memory device; and generating a refresh request for one or more memory cells of the semiconductor memory device according to the error handling information.

In the operating method, the monitoring error handling information may comprise storing an address of the memory cell where an error has occurred and a number of errors that has occurred at the address of the memory cell.

In the operating method, the monitoring error handling information may comprise determining an error that has occurred is a soft error and storing an address of the memory cell when the error has occurred and a number of errors that has occurred at the address of the memory cell if the error is the soft error.

In the operating method, the generating a refresh request may comprise checking the number of errors at the stored address and generating the refresh request for the memory cells whose number of errors is not smaller than a predetermined threshold value.

In the operating method, the generating a refresh request may comprise generating a request enabling a word line which is connected to the memory cells whose number of errors is not smaller than a predetermined threshold value.

In the operating method, the checking may be executed every predetermined period shorter than a normal refresh period of the semiconductor memory device.

In an embodiment, a semiconductor device may comprise: an ECC block checking a data and generating error handling information; and a monitoring block generating a refresh request for one or more memory cells according to the error handling information.

In the semiconductor device, the monitoring block may comprise an error register for storing error information according to the error handling information from the ECC block and a controller for controlling the error register to store the error information and for generating a refresh request for one or more memory cells of the semiconductor memory device according to the error information stored in the register.

In an embodiment, a system may comprise: a semiconductor memory device; and a memory controller for controlling the operation of the semiconductor memory device, wherein the memory controller may comprise an ECC block checking a data and generating error handling information; and a monitoring block generating a refresh request for one or more memory cells according to the error handling information.

In the system, the monitoring block may comprise an error register for storing error information according to the error handling information from the ECC block and a controller for controlling the error register to store the error information and for generating a refresh request for one or more memory cells of the semiconductor memory device according to the error information stored in the register.

In an embodiment, a storage medium storing processes executed by a processor, wherein the processes may comprise providing error handling information for a data read from a semiconductor memory device; and generating a refresh request for one or more memory cells of the semiconductor memory device according to the error handling information.

In an embodiment, a semiconductor device may comprise: an ECC block providing error detection information; and a controller configured to store the error detection information at an error register and request a refresh operation.

In an embodiment, the data structure of the error detection information stored in the error register may include a valid field, an address field, and a count field.

In an embodiment, the controller may determine whether there is a correctable error when the ECC block provides the error detection information.

In an embodiment, the controller may determine whether the correctable error is a soft error or a hard error.

In an embodiment, the refresh operation requested by the controller may be executed for a limited number of memory cells.

In an embodiment, a memory system comprises: a semiconductor memory device and a semiconductor device. The semiconductor device comprises: an ECC block checking a data and generating error handling information; and a monitoring block generating a refresh request for one or more memory cells according to the error handling information.

In an embodiment, an electronic device comprises: a memory system communicatively coupled to a central processing unit; the memory system including a semiconductor device. The semiconductor device comprises: an ECC block checking a data and generating error handling information; and a monitoring block generating a refresh request for one or more memory cells according to the error handling information.

### BRIEF DESCRIPTION OF THE DRAWINGS

FIG. 1 is a block diagram illustrating a semiconductor device in accordance with an embodiment of the present invention.

FIG. 2 is a diagram illustrating a data structure of error register in accordance with an embodiment of the present invention.

FIG. 3 is a flow chart illustrating monitoring operation of the semiconductor device in accordance with an embodiment of the present invention.

FIG. 4 is a flow chart illustrating a special refresh operation of the semiconductor device in accordance with the embodiments of the present invention.

FIG. 5 is a block diagram illustrating a memory system according to an embodiment of the present invention.

FIG. 6 is a view illustrating an electronic device or a computing system according to an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

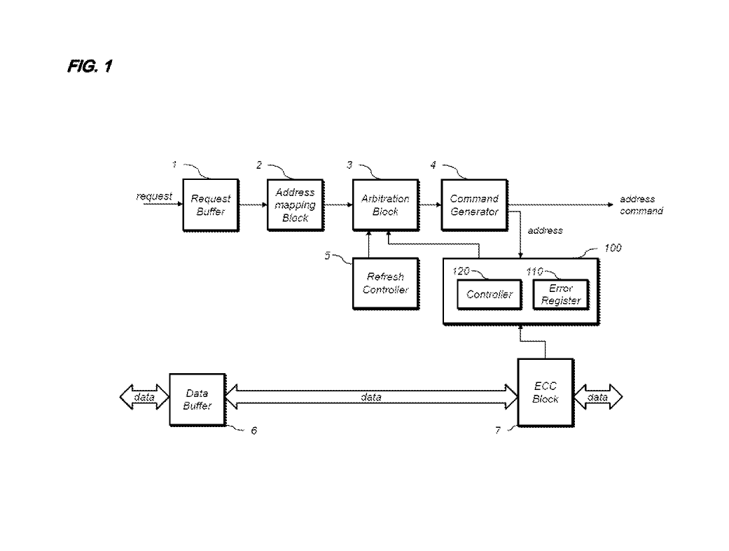

FIG. 1 is a block diagram illustrating a semiconductor device in accordance with an embodiment of the present invention.

The semiconductor device in accordance with the embodiments of the present invention may be embodied as a memory controller for controlling a semiconductor memory device or a processor including the memory controller. Therefore memory controller in the disclosure may designate a memory controller itself or a processor including the memory controller therein.

The semiconductor device in FIG. 1 may include a request buffer 1; an address mapping block 2 which maps a logical address from a host to a physical address of the semiconductor memory device; a command generator 4 for generating a command and an address for controlling the semiconductor memory device corresponding to a request from the host; a refresh controller 5 for controlling normal refresh operation of a semiconductor memory device which is executed periodically; and a data buffer 6 for temporarily storing a data to and from the host and an error-correction code (ECC) block 7 which senses error from the semiconductor memory device and corrects the error.

An arbitration block 3 may determine processing order of requests from host, from the refresh controller 5 and from the monitoring block 100.

The ECC block 7 may provide error handling information, such as error detection or error correction information of a data read from the semiconductor memory device to the monitoring block 100.

The monitoring block 100 may comprise an error register 110 storing error information according to the error handling information from the ECC block 7 and a controller 120 controlling to store the error information at the error register 110 and to request a special refresh operation referring to the error register 110.

Since hard errors cannot be removed by refresh operations, the monitoring block 100 may store error information only on soft errors.

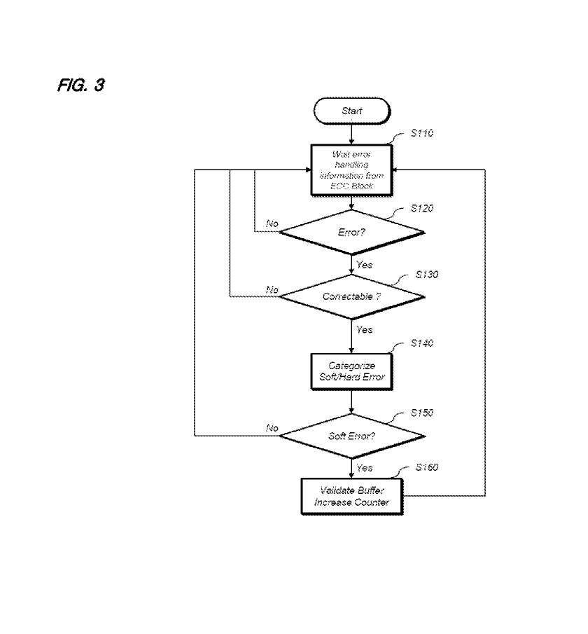

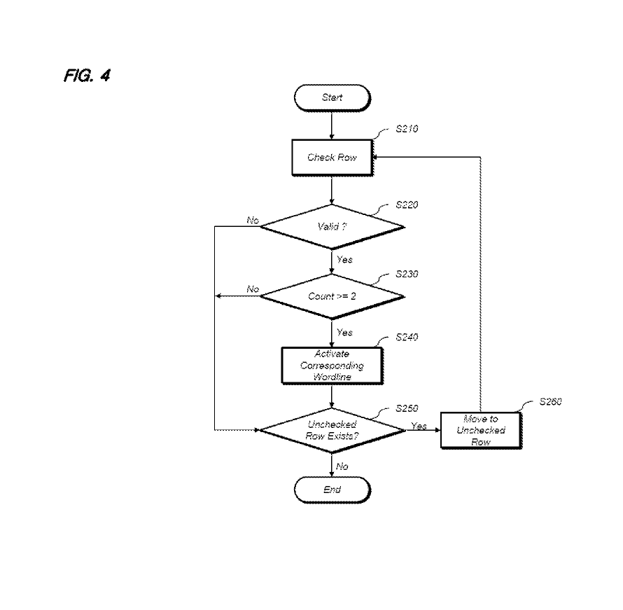

The specified operating method of the monitoring block 100 according to an embodiment of the present invention may be described with reference to FIGS. 3 and 4.

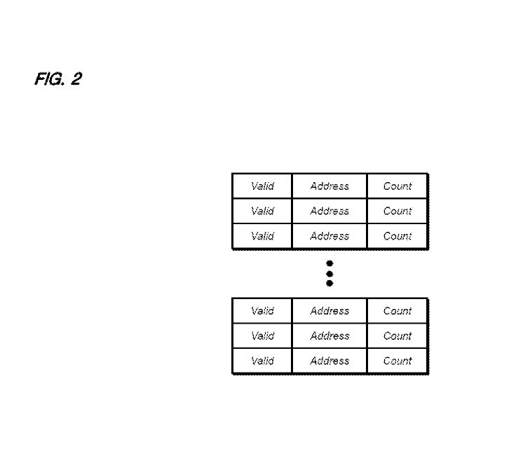

FIG. 2 illustrates a data structure of error information stored in the error register 110 according to an embodiment of the present invention.

The data structure may include a valid field, address field and count field.

The valid field may store a flag bit whether the row corresponding the valid field include valid data or not.

The address field may store the address of a memory cell of the semiconductor memory device. The address field may include only a part of the address such as a row address of the memory cell.

The count field may store a number of errors that have occurred at the address stored in the address field. The count field may store a number of soft errors.

FIG. 3 is a flow chart illustrating monitoring operation of the semiconductor device in accordance with an embodiment of the present invention.

The controller 120 in the monitoring block 100 may await error handling information from the ECC block 7 at step S110.

If error handling information comes from the ECC block 7, the controller 120 may check the error handling information to determine whether error has occurred at step S120.

If error has occurred, the controller 120 may determine whether the error is a correctable error at step S130. If error has not occurred or the error is not correctable, the controller 120 may await another error handling information at step S110.

If the error is correctable, the controller 120 may categorize the error as a soft error or as a hard error at step S140. To categorize the error as a soft error or as a hard error, the controller 120 may use a method known in the prior art such as U.S. Pat. No. 4,604,751.

The controller 120 may determine whether the error is a soft error or a hard error at step S150. If the error is a hard error, the controller 120 may await another error handling information at step S110.

If the error is a soft error, the controller 120 may find a valid row in the data structure illustrated in FIG. 2 having an address where the error has occurred and increase count value in the row at step S160. If there is no valid row in the data structure having the address where the error has occurred, a new row may be validated to have the address where the error has occurred and the count value is set to 1 at step S160. The controller 120 may await another error handling information at step S110.

FIG. 4 is a flow chart illustrating a special refresh operation of the semiconductor device in accordance with the embodiments of the present invention.

The error to be handled in an embodiment of the present invention cannot be remedied by a normal refresh operation executed every refresh period tREF such as 64 ms.

The operation described in FIG. 4 may be executed between normal refresh operations controlled by the monitoring block 100 or may be executed every period smaller than the normal refresh period tREF.

The special refresh operation activated according to the FIG. 4 is not executed for all memory cells but for limited memory cells where a predetermined number or more errors have occurred.

The controller 120 may check a row at step S210 and determine whether the row is valid or not at step S220.

If the row is not valid the process jumps to step S250. If the row is valid, the controller 120 may check whether the count value in the count field is as large as or larger than a predetermined threshold value such as 2 at step S230.

If the count value is smaller than the threshold value, the process jumps to step S250. If the count value is not smaller than the threshold value, the controller 120 may generate a special refresh request to activate the row and provides the special refresh request to the arbitration block 3. When arbitration block 3 receives the special refresh request, the arbitration block may schedule the special refresh request and then the command generator 4 may provide one or more commands to control a semiconductor memory device to activate the row as designated in the special refresh request.

After refreshing the row at step S240, the controller 120 may determine whether there is an unchecked row at step S250.

If there is an unchecked row, the controller 120 may move to an unchecked row at step S260 and the process goes back to the step S210. If there is no unchecked row the process ends.

As described above, an embodiment according to the present invention may decrease the chances of error happening by VRT in a semiconductor memory device.

The controller 120 may comprise a processor and a program register. The operations described in FIG. 3 and FIG. 4 may be stored as program codes in the program register such as read-only memory (ROM), NAND flash memory device and etc.; and the operations may be conducted and controlled by the processor which may execute the program codes read from the program register.

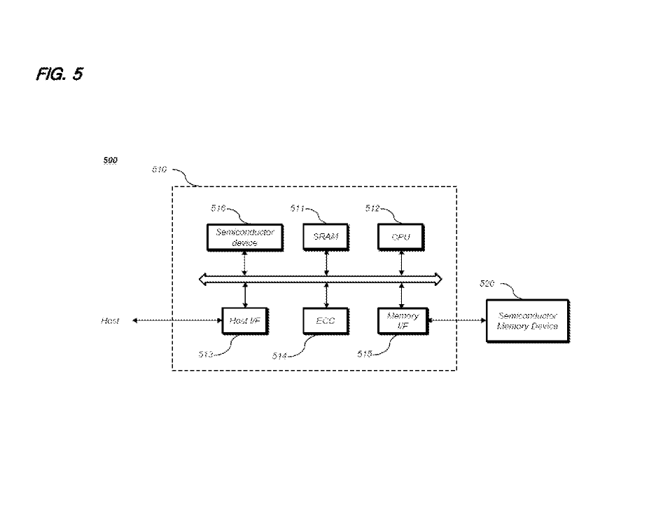

FIG. 5 is a block diagram illustrating a memory system according to an embodiment of the present invention.

In accordance with the embodiments of the present invention, a semiconductor device may be embodied as a memory controller for controlling a semiconductor memory device or a processor including the memory controller. In FIG. 5, the memory system 500 of the present embodiment may include a semiconductor memory device 520, a memory controller 510, and a central processing unit (CPU) 512.

The semiconductor memory device 520 may serve as a volatile memory device such as a DRAM or a nonvolatile memory such as a Magnetoresistive random-access memory (MRAM), spin transfer torque-MRAM (STT-MRAM), phase-change memory (PCRAM), resistive random-access memory (ReRAM), or ferroelectric RAM (FeRAM). The semiconductor memory device 520 may be a multi-chip package having flash memory chips.

The memory controller 510 may control the semiconductor memory device 520, and may include a static random-access memory (SRAM) 511, a host interface 513, an ECC 514, and a memory interface 515. The SRAM 511 may be used as an operation memory of the CPU 512. The CPU 512 may perform control operation for data exchange of the memory controller 510, and the host interface 513 may have data exchange protocol of a host accessed to the memory system 500. The ECC 514 may detect and correct error of data read from the semiconductor memory device 520, and the memory interface 515 may interface with the semiconductor memory device 520. The memory controller 510 may include further ROM for storing data for interfacing with the host, etc.

The memory system 500 may be used as a memory card or a solid state disk SSD by combination of the semiconductor memory device 520 and the memory controller 510. In the event that the memory system 500 is the SSD, the memory controller 510 may communicate with an external device, e.g. host through one of the various interface protocols such as USB, MMC, PCI-E, SATA, PATA, SCSI, ESDI, IDE, etc.

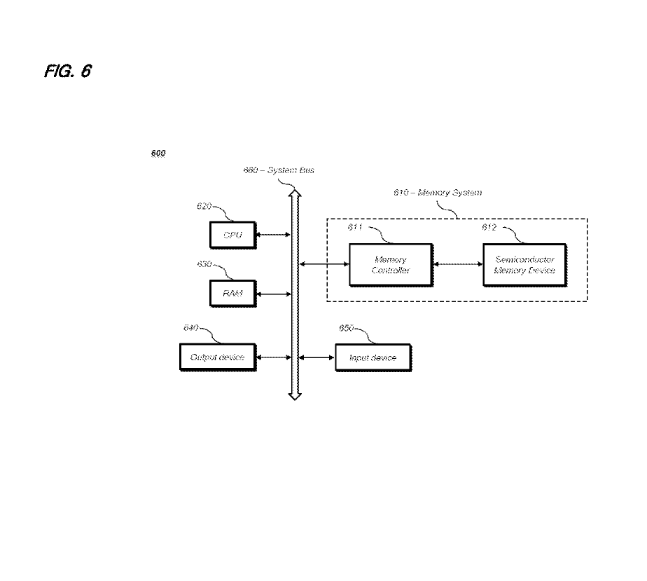

FIG. 6 is a view illustrating an electronic device or a computing system according to an embodiment of the present invention.

In FIG. 6, the computing system 600 of the present embodiment may include CPU 620 connected electrically to a system bus 660, a RAM 630, an output device or user interface 640, an input device 650, and a memory system 610 including a memory controller 611 and a semiconductor memory device 612. In case that the computing system 600 is a mobile device, a battery (not shown) for supplying an operation voltage to the computing system 600 may be further provided. The computing system 600 of the present invention may further include an application chipset, a complementary-metal-oxide semiconductor (CMOS) image processor CIS, a mobile DRAM, etc.

The output device or user interface 640 may be a self-contained display in the case of a portable electronic device. The input device 650 may be a physical keyboard or a virtual keyboard in the case of a portable electronic device, and may further include, without limitation, a trackball, touchpad, or other cursor control device combined with a selection control, such as a pushbutton, to select an item highlighted by cursor manipulation. The memory system 610 may include a semiconductor memory device as described in FIG. 5.

Although various embodiments have been described for illustrative purposes, it will be apparent to those skilled in the art that various changes and modifications may be made without departing from the spirit and scope of the invention as defined in the following claims.

What is claimed is:

1. An operating method of a semiconductor device comprising:
monitoring error handling information for a data read from a semiconductor memory device; and
generating a refresh request for one or more memory cells of the semiconductor memory device according to the error handling information.

2. The operating method of claim 1, wherein the monitoring error handling information comprises storing an address of the memory cell where an error has occurred and a number of errors that has occurred at the address of the memory cell.

3. The operating method of claim 1, wherein the monitoring error handling information comprises determining an error that has occurred is a soft error and storing an address of the memory cell when the error has occurred and a number of errors that has occurred at the address of the memory cell if the error is the soft error.

4. The operating method of claim 2, wherein the generating a refresh request comprises checking the number of errors at the stored address and generating the refresh request for the memory cells whose number of errors is not smaller than a predetermined threshold value.

5. The operating method of claim 4, wherein the generating a refresh request comprises generating a request enabling a word line which is connected to the memory cells whose number of errors is not smaller than a predetermined threshold value.

6. The operating method of claim 4, wherein the checking is executed every predetermined period shorter than a normal refresh period of the semiconductor memory device.

7. A semiconductor device comprising:
an ECC block checking a data and generating error handling information; and
a monitoring block generating a refresh request for one or more memory cells according to the error handling information

8. The semiconductor device of claim 7, wherein the monitoring block comprises
an error register for storing error information according to the error handling information from the ECC block and
a controller for controlling the error register to store the error information and for generating a refresh request for one or more memory cells of the semiconductor memory device according to the error information stored in the register.

9. The semiconductor device of claim 8, wherein the error information includes an address where an error has occurred and a number of errors that have occurred at the address.

10. The semiconductor device of claim 9, wherein the error is a soft error.

11. The semiconductor device of claim 7, wherein the refresh request is executed between normal refresh requests.

12. The semiconductor device of claim 8, further comprising:
an arbitration block for determining an processing order of the refresh request; and
a command generator for generating a refresh command for controlling the refresh operation of the semiconductor memory device corresponding to the refresh request.

13. A system comprising:
a semiconductor memory device; and
a memory controller for controlling the operation of the semiconductor memory device, wherein the memory controller comprises:
an ECC block checking a data for generating error handling information of the data; and
a monitoring block generating a refresh request for one or more memory cells according to the error handling information .

14. The system of claim 7, wherein the monitoring block comprises
an error register for storing error information according to the error handling information from the ECC block and
a controller for controlling the error register to store the error information and for generating a refresh request for one or more memory cells of the semiconductor memory device according to the error information stored in the register.

15. The system of claim 8, wherein the error information includes an address where an error has occurred and a number of errors that have occurred at the address.

16. The system of claim 15, wherein the error is a soft error.

17. The system of claim 15, wherein the refresh request is executed between normal refresh requests.

18. The system of claim 13, wherein the memory controller further comprises:
an arbitration block for determining an processing order of the refresh request; and
a command generator for generating a refresh command for controlling the refresh operation of the semiconductor memory device corresponding to the refresh request.

19. A storage medium storing processes executed by a processor, wherein the processes comprise:
providing error handling information for a data read from a semiconductor memory device; and
generating a refresh request for one or more memory cells of the semiconductor memory device according to the error handling information.

20. The storage medium of claim 19, wherein the refresh request is executed between normal refresh requests.
